(19) United States
(12) Patent Application Publication
(10) Pub. No.: US 2022/0149225 A1
(43) Pub. Date: May 12, 2022

(54) METHOD OF PRODUCTION OF SILICON HETEROJUNCTION SOLAR CELLS WITH STABILIZATION STEP AND PRODUCTION LINE SECTION FOR THE STABILIZING STEP

(71) Applicant: MEYER BURGER (GERMANY) GMBH, Hohenstein-Ernstthal (DE)

(72) Inventor: Steffen FRIGGE, Lichtenwalde (DE)

(73) Assignee: MEYER BURGER (GERMANY) GMBH, Hohenstein-Ernstthal (DE)

(21) Appl. No.: 17/438,685

(22) PCT Filed: Apr. 29, 2020
(86) PCT No.: PCT/DE2020/100353

§ 371 Date: Sep. 13, 2021

(30) Foreign Application Priority Data
Apr. 29, 2019 (DE) 10 2019 111 061.0

(51) Int. Cl. H01L 31/18; H01L 31/20; H01L 31/0747

(52) U.S. Cl. CPC H01L 31/1864; H01L 31/0747; H01L 31/202

(57) ABSTRACT

The present invention relates to a method of production of silicon heterojunction solar cells having at least one stabilization step, wherein the stabilization step is performed after amorphous silicon layers, and preferably also transparent layers or even metallic contact materials, have already been applied beforehand to crystalline silicon solar wafers. The problem addressed by the invention consists in finding an efficient stabilization step which permits high solar cell efficiencies. The problem is solved by a method of production of silicon heterojunction solar cells in which the stabilization step comprises heating the solar cell to temperatures above 200° C. and illumination from a light source, wherein the light source emits light in a wavelength range <2 500 nm and wherein one of the light doses emitted by the light source is in excess of 8 000 Ws/m².

The present invention relates to a method of production of silicon heterojunction solar cells having at least one stabilization step, wherein the stabilization step is performed after amorphous silicon layers, and preferably transparent layers or even metallic contact materials, have already been applied beforehand to crystalline silicon solar wafers, as well as an accordingly equipped production line section.

Silicon heterojunction solar cells are high-performance solar cells (HJT solar cells for short) that achieve higher levels of efficiency than other solar cell types that are currently being mass-produced on an industrial scale. Two different semiconductor materials meet at the hetero-pn-junction of this solar cell. During the method of production of silicon heterojunction solar cells, a crystalline silicon wafer, which later forms the basis of the solar cell, is initially provided. The crystalline silicon of this solar wafer is the first semiconductor material. At least one layer of another silicon material, in particular amorphous silicon, is deposited on this wafer in order to form the detector of the solar cell. As a rule, a further layer of amorphous silicon material is also deposited on the side of the solar cell opposite the emitter, for example to create a potential gradient across the solar cell and to feed charge carriers, i.e. electrons and holes produced with the photo effect, to the external contacts of the solar cell conduct. Often, thin undoped amorphous intermediate layers are deposited between the interfaces of the crystalline silicon and the other doped silicon layers. Amorphous silicon has a larger band gap than crystalline silicon and can therefore convert short-wave light into electrical energy more effectively than crystalline silicon. In the combination of both silicon materials, the incident solar spectrum on earth can be used more effectively than pure crystalline Si solar cells. The HJT solar cells also have fewer recombination centres at which electrons and holes can recombine than conventional solar cells. This increases the probability that the separated electrons and holes will reach the external contacts of the solar cell and the efficiency of the solar cell increases accordingly. HJT solar cells can be damaged by excessively high temperatures in the method of production because the amorphous or nanocrystalline deposited layers change their structure or crystallize at temperatures of around 200° C. and can irreversibly damage the solar cell. In method of production of HJT solar cells from the prior art, only low temperatures below 200° C. are therefore usually used, for example in US 2015/0013758 A1. For the production of metallic contacts e.g. from metal pastes and/or foil wire electrodes and for the stabilization of produced solar cell properties, higher temperatures would in some cases also be desirable, but the maximum possible temperatures in the prior art are around 350° C., for example in U.S. Pat. No. 7,754,962 B2.

U.S. Pat. No. 7,754,962 B2 also describes an advantageous stabilizing effect through a combination of illumination and tempering, with existing upper temperature limits not being allowed to be exceeded.

Highly effective solar cells can only move into industrial production to a significant extent if the costs of the method of production or the energy production costs with these solar cells are sufficiently low. For years or decades, heterojunction technology has faced the challenge of finding ways to achieve the required cost reduction. In addition, higher efficiencies are required for the HJT solar cells (than with mature, established technologies). A degradation of the initial efficiencies of solar modules produced from the solar cells is to be minimized or avoided as far as possible in order to ultimately guarantee high usable efficiencies for many years. All sub-steps of the method of production have to contribute to the solution of these general tasks, including the stabilization step at the end of the method of production, the task of which is to stabilize the high efficiency of the solar cells at the beginning and to minimize gradual deterioration or degradation of the efficiency.

Therefore, the object of the invention is to find an efficient stabilization step that enables high solar cell efficiencies.

The object is achieved by methods of production of silicon heterojunction, in which the stabilization step includes heating the solar cell to temperatures above 200° C. and an illumination from a light source, wherein the light source emits light in a wavelength range <2 500 nm and wherein one of the light doses emitted by the light source is >8 000 Ws/m². Light quanta of different energies have different effects on the solar cell. According to the sunlight spectrum, radiation in the visible spectral range and in the adjacent areas, namely the near infrared range and the ultraviolet range, is referred to as light. Light with a photon energy above 1.1 eV and a wavelength below 1 100 nm is in the operating range of the silicon solar cell because the energy of the photons and the photoelectrons generated from them is greater than the band gap of crystalline silicon. Effects other than the generation of photoelectrons, which are involved in stabilization processes in the solar cell, require other critical photon energies. When the solar cell is stabilized, various effects with different physical and chemical mechanisms of action take place. Some of these mechanisms take place as a result of sufficiently high heat. Sufficiently high-energy photons or sufficiently high-energy charge carriers are sometimes required to trigger the required effects in the solar cell. The various effects that take place include the finding of more stable bond states of atoms in amorphous layers, the loosening of weakly bonded hydrogen atoms, the diffusion of hydrogen and the binding of hydrogen to free binding sites. A light dose of 8 000 Ws/m² can be provided, for example, by applying a radiant power density of 1 000 W/m² for 8 s. If the same light output is concentrated on a smaller area, the light dose on the smaller area increases accordingly. A radiant power density of 1 000 W/m² is also referred to as 1 sun, because the earth is illuminated by the sun with such a radiant power density.

Both process components, the heat treatment and the illumination, contribute to the stabilization of the solar cell. Stabilization means that degradation of the performance parameters of the solar cell produced is reduced. The performance parameters include short circuit current, series resistance, open circuit voltage, fill factor and efficiency (ETA). In some cases, the stabilization step also has the effect of improving the initial efficiency if a method of production without the stabilization step is used as a reference. The solar cell is illuminated with intense light. Since the effect of the light treatment usually runs faster with stronger illumination, the intensity of the illumination is selected as large as possible. In various exemplary embodiments, the intensity of the illumination is between 1 sun and 100 suns. Upper limits of the illuminance result from the heating of the solar cell associated with the illumination and from the availability of suitable light sources. The product of the illumination power density and the treatment time gives an effective light dose, e.g. irradiation with 1 000 W/m² over a period of 10 s results in a dose of 10 000 Ws/m². With high light outputs, non-linear effects sometimes occur, so that the dose is only partially a suitable reference value. With commercially available LED spotlights, power radiant densities of 50 000 W/m² can be achieved, with a focusing of the light also more accordingly.

In the interest of an effective and fast production of the solar cells, all sub-steps of the process are performed as quickly as possible. Accordingly, the stabilization step of the method of production according to the invention can also be trimmed towards short process times and fast throughput times. The stabilization step is preferably performed within a short cycle time (of e.g. 30 s) which is predetermined in the production line or in a section thereof. A constant illuminance can be used during the processing time. However, a time and/or location-dependent illuminance can also be used. The illumination can also be chopped up in a pulse-like manner. Various requirements can be placed on the method of production. While high profitability and minimizing costs are always important target parameters in mass production, other target parameters, such as maximum efficiency regardless of profitability, can also be rated higher in other cases. Depending on the specific requirements, the process can be designed accordingly. The stabilization step can take place at various points in the method of production, for example after the various depositions of silicon layers, passivation layers and optical layers have already taken place. However, a stabilization step can also be performed after the deposition of a silicon layer, for example still within the deposition system. Several stabilization steps or partial stabilization steps can be performed in each case after a layer has been deposited.

For reasons of effectiveness, all deposited layers are preferably post-treated together in the stabilization step, with metallic contact materials also having preferably already been applied, so that the stabilization step can also fulfil a partial task in the production of the metallic contacts among several different sub-tasks.

The electrical connection of HJT solar cells is usually carried out in two stages from the inside to the outside. Inside the solar cell, in the first stage, the silicon surfaces are generally enclosed over the whole area by transparent conductive layers, in particular TCO layers such as ITO, wherein the transparent layers also have other functions in addition to electrical functions, in particular those of anti-reflective layers and/or encapsulation layers. Externally, the transparent conductive layers can be connected to metal fingers or other metal structures, which can be viewed as part of the second stage of the solar cell connections. These metal structures can be produced from low-temperature metal pastes, for example by screen printing, connection structures with metallic properties only being created from the metal pastes during a heat treatment. In addition to the metal fingers, busbars can also be produced by screen printing. However, other printing technologies, conductive adhesives and the like can also be used, with various technologies for producing metallic contacts requiring temperature treatments, which are often also referred to as curing. Solar cells without busbars are later able to be processed into, for example, solar modules using foil-wire electrodes from Smartwire Connection Technology (SWCT). The metal temperature treatment or metal curing and the stabilization step can be combined into a single step of the method of production.

After the metal contacts have been made, solar cells are usually measured and classified. In the method according to the invention, the stabilization step has already been completed during the measurement, so that the solar cells are classified with stable solar cells. Other stabilization methods, which only take place after the measurement of the solar cells, are associated with greater fluctuations in solar cell properties. Since some or all solar cells in solar modules are electrically connected in series and the worst solar cell determines the performance of the entire series circuit, a reliable electrical characterization of solar cells without subsequent deterioration due to fluctuating degradation is of great importance. This means that equally good solar cells can be built into modules later and maximum module performance can be achieved.

The stabilization step of the method of production according to the invention can include a temperature treatment with a temperature peak of no more than 10 seconds at temperatures above 350° C. Changes in the (amorphous) layer structure, in extreme cases crystallization processes, are not only dependent on the temperature, but also on the time of the temperature treatment. For longer processing times, please note that temperatures above 200° C. can damage the HJT solar cell. However, Si-HJT solar cells can also be heated to over 350° C. for a short time for up to 10 s. For times of less than one minute, temperatures higher than 200° C. are also possible, for example 220° C. for 20 s. Such high temperature peaks on the one hand result in short processing times and correspondingly short throughput times. On the other hand, the short temperature peaks can also bring about improved stabilization effects. The temperature peak can also reach temperatures above 400° C. if the times are sufficiently short with values between 1 and 5 seconds. At lower temperatures below 200° C., short processing times in the range of seconds are also desirable for productivity reasons. For serious reasons, however, a long illumination and/or temperature treatment time of, for example, a few hours or days can be selected, for example in order to achieve maximum stabilization effects for a few demonstration solar cells. In suitably constructed plants, very long processes can also be performed cost-effectively for mass production.

If metallic contact materials have been applied in a previous step of the method of production according to the invention, the temperature treatment can also make a contribution to the production of metallic contacts from the metallic contact materials. Viewed the other way around, the existing processing step of the temperature treatment of metallic contact materials can be modified and supplemented in such a way that a better stabilization of the solar cell is additionally achieved in the existing method step.

The light treatment as part of the stabilization step can be performed with halogen or LED lamps for at least 1 s. In addition to the radiation component in the visible spectral range, the light from halogen lamps also has large radiation components in the near infrared and in the infrared spectral range, so that halogen lamps can also be used as heat sources for simultaneous heating during illumination. Another advantage of halogen lamps is their insensitivity to temperature. The entire available time can also be used in slower process steps. If, for example, 5 min process time is available in a drying oven, then the entire process time can be used for treatment with heat and light. The light sources, for example the halogen lamps, can also be used as heat sources at the same time. In continuous systems, the combination of space and cycle time often results in shorter possible treatment times. With LED lamps, higher light intensities are possible than with halogen lamps with the same heating of the solar cells. If LED lamps are properly cooled and controlled, they can have a significantly longer service life than halogen lamps. The halogen or LED lamps can be composed of several individual lamp elements. Due to the heating under strong illumination, the usable maximum power density is limited with uncooled substrates. In the case of cooled substrates, a higher radiation power density can be used, the limits being higher for LED lamps than for halogen lamps. If heat filters are used, even higher outputs are possible.

With a light treatment with LED lamps, a power density between 100 and 100 000 W/m² can be used. Since LED lamps emit less heat radiation than halogen lamps, high power densities can be used even with uncooled substrates. With suitable cooling measures, even higher power densities can be achieved.

In the case of long treatment times, for example in a light storage device for stabilization steps lasting minutes, hours or days, a saturation of the stabilization effect can be achieved even with a low radiation power density of, for example, 100 W/m². The light treatment can also be carried out with a high-intensity light source, in particular a laser or a flash lamp with a power density of up to 100 000 W/m². With laser light, high power densities can be achieved, which optically can be handled precisely due to the coherence of the laser light. With lasers, therefore, particularly fast and precise processing is possible. High power densities can also be achieved with flash lamps.

In the method of production according to the invention, the solar cell can be heated and illuminated partially or completely by a light source. Since existing temperature limits of the HJT solar cell must be observed and there is always a corresponding heating during strong illumination, the heating accompanying the illumination can also be used as heating. In this way, existing performance and temperature limits can be optimally used. With this option, the stabilization step can be implemented particularly effectively and simply in terms of the system.

The object of the invention is also achieved in a second aspect by a production line section for performing the stabilization step of the method of production according to the invention, wherein the production line section has a heating section for performing the temperature treatment and a light treatment section for performing the light treatment. The heating section and the light processing section may be separate sections. Both sections can, for example, be arranged spatially one behind the other in a continuous system. However, both sections can also be designed as separate areas of a system or as separate systems.

Both areas can also overlap one another, for example the light treatment section can essentially extend through an entire continuous system and the heating section can be implemented in a central subsection of the same continuous system. A temporal separation of the temperature treatment and the light treatment can also be implemented by different start and/or end times of the operation of light and heat sources, wherein the heat treatment section and the light treatment section can also be spatially identical.

The heating section and the light treatment section can also be combined spatially and temporally, so that the heating component and the illumination component of the stabilization step coincide spatially and temporally and result in a common method step.

In a preferred exemplary embodiment, the production line section according to the invention is realised as a continuous furnace section with transparent transport rollers. In this continuous furnace, the solar cells are irradiated by halogen spotlights both on their side lying on top and on their opposite front side, which simultaneously serve as a heat source and a light source. The entire run through the continuous furnace section takes between 1 s and 30 s. In a middle temperature treatment section, the halogen radiators are arranged close to each other and to the passing solar cells in such a way that during the run, the solar cells are heated to more than 400° C. for 5 s.

1-10. (canceled)

11. Method of production of silicon heterojunction solar cells having at least one stabilization step, wherein the stabilizing step is performed after amorphous silicon layers, and preferably transparent layers or even metallic contact materials, have already been applied beforehand to crystalline silicon solar wafers,
wherein the stabilization step includes heating the solar cell to temperatures above 200° C. and an illumination from a light source, wherein the light source emits light in a wavelength range <2 500 nm and wherein one of the light doses emitted by the light source is in excess of 8 000 Ws/m², and wherein the stabilization step includes a temperature treatment with a temperature peak of no more than 10 seconds at temperatures above 350° C.

12. Method of production according to claim 11, wherein the temperature peak with temperatures above 400° C. lasts between 1 and 5 seconds.

13. Method of production according to claim 11, wherein, in a previous step of the method of production, metallic contact materials have been applied, and the temperature treatment also contributes to the production of metallic contacts from the metallic contact materials.

14. Method of production according to claim 11, wherein the light treatment is performed with halogen or LED lamps for at least 1 s.

15. Method of production according to claim 14, wherein the light treatment is performed with halogen lamps with a power density of between 1 000 and 10 000 W/m², preferably on cooled substrates.

16. Method of production according to claim 14, wherein the light treatment is performed with LED lamps with a power density of between 100 and 100 000 W/m².

17. Method of production according to claim 11, wherein the light treatment is performed with a high intensity light source, in particular a laser or a flash lamp with a power density of up to 100 000 W/m².

18. Method of production according to claim 11, wherein the heating and illumination of the solar cell is done partially or completely by a light source.

19. Production line section for performing the production process according to claim 11, wherein the production line section has a heating section for performing the temperature treatment and a light treatment section for performing the light treatment.

20. Production line section according to claim 19, wherein the production line section is realised as part of a continuous furnace, wherein the light treatment section is equipped with transparent transport rollers.
